(19) United States
(12) Patent Application Publication
(10) Pub. No.: US 2026/0082712 A1
(43) Pub. Date: Mar. 19, 2026

(54) BACKSIDE ILLUMINATED IMAGE SENSOR AND METHOD OF MANUFACTURING SAME

(71) Applicant: DB HiTek Co., Ltd., Bucheon-si (KR)

(72) Inventors: Chang Hun HAN, Icheon-si (KR); Man Lyun HA, Mungyeong-si (KR); Kang Hoon LEE, Gunpo-si (KR)

(21) Appl. No.: 18/940,396

(22) Filed: Nov. 7, 2024

(30) Foreign Application Priority Data
Sep. 13, 2024 (KR) 10-2024-0125647

(51) Int. Cl. H01L 27/146

(52) U.S. Cl. CPC H10F 39/199; H10F 39/024; H10F 39/8057; H10F 39/811

(57) ABSTRACT

A backside illuminated image sensor and a method of manufacturing the same include an upper conductive film formed within a separation space of substrates but not formed on back surfaces of the substrates, thereby reducing the overall thickness of a structure formed on the back surfaces of the substrates within a pad region, thereby preventing a stripe-like pattern (striation) from forming on the substrates and preventing damage to a corner portion of the upper conductive film.

### CROSS REFERENCE TO RELATED APPLICATION

The present application claims priority to Korean Patent Application No. 10-2024-0125647, filed September 13, 2024, the entire contents of which is incorporated herein for all purposes by this reference.

### BACKGROUND OF THE INVENTION

### Field of the Invention

The present disclosure relates generally to a backside illuminated image sensor and a method of manufacturing the same. More particularly, the present disclosure relates to a backside illuminated image sensor and a method of manufacturing the same, in which an upper conductive film is formed within a separation space of substrates but is not formed on back surfaces of the substrates, thereby reducing the overall thickness of a structure formed on the back surfaces of the substrates within a pad region, thereby preventing a stripe-like pattern (striation) from forming on the substrates and preventing damage to a corner portion of the upper conductive film.

### DESCRIPTION OF THE RELATED ART

An image sensor is a component of an image-capturing device that generates an image in a mobile phone camera or the like. Image sensors can be classified into a charge coupled device (CCD) image sensor and a complementary metal oxide semiconductor (CMOS) image sensor, depending on manufacturing processes and applications. Of these, the CMOS image sensor has been widely used as a general semiconductor chip manufacturing process due to its excellent integration competitiveness, economic feasibility, and ease of connection with peripheral chips.

In a conventional frontside illuminated CMOS image sensor, wiring portions may be formed sequentially on a front surface of a silicon wafer. However, an image sensor with such a structure is problematic in that the amount of incident light received by a light receiving element is reduced due to metal wirings within the wiring portions. In response to this, there has been developed a backside illuminated CMOS image sensor (BIS) in which a wiring portion is disposed on a front surface of a substrate and light is incident on a back surface of the substrate.

FIG. 1 is a sectional view illustrating the structure of a conventional backside illuminated image sensor; FIG. 2 is a reference view illustrating a problem occurring during a spin coating process in the structure of the backside illuminated image sensor illustrated in FIG. 1; and FIG. 3 is a view illustrating damage to a corner portion of a conductive film in the structure of the backside illuminated image sensor illustrated in FIG. 1.

Hereinafter, the structure of the conventional backside illuminated image sensor 9 and the problems arising therefrom will be described in detail with reference to the accompanying drawings.

Referring to FIG. 1, the conventional backside illuminated image sensor 9 includes a lower insulating film 920 on front surfaces 911 of a pair of substrates 910, each of which having a front surface 911 and a back surface 913, within a pad region A3. Additionally, an adhesive layer 940 is formed on a metal layer 921a formed in a separation space A31 of the substrates 910, and a conductive film 950 is formed on the adhesive layer 940. Additionally, an insulating film 930 is formed between the adhesive layer 940 and the substrates 910. At this time, the conductive film 950 extends from the adhesive layer 940 in the separation space A31 of the substrates 910 to sidewalls of the substrates 910 and back surfaces 913 of the substrates 910. That is, the conductive film 950 is formed on the adhesive layer 940 on the back surfaces 913 of the substrates 910. Accordingly, due to the insulating film 930, the adhesive layer 940, and the conductive film 950 formed on the back surfaces 913 of the substrates 910 within the pad region A3, a thickness B1 of the entire structure B (see FIG. 2) formed on the back surfaces 913 is likely to be relatively large.

Referring to FIG. 2, when forming a color filter and/or micro-lens of the backside illuminated image sensor 9, a spin coating process is performed on a photosensitive liquid. At this time, the photosensitive liquid may not be evenly applied due to the structure formed on the back surface 913 of the substrate 910, but clump on a side adjacent to the structure, resulting in a stripe-like pattern ST formed on the substrate 910. This may act as a factor causing poor appearance and color deviation of the image sensor 9.

Furthermore, referring to FIG. 3, when forming a photoresist film PR on the conductive film 950 on the back surfaces 913 of the substrates 910 to complete the conductive film 950, a corner portion of the photoresist film PR is formed relatively thin, so loss is likely to occur in the conductive film 950 directly below the photoresist film PR. That is, a corner portion of the conductive film 950 is etched undesiredly. As a result, a problem arises in that the corner portion of the completed conductive film 950 may be damaged.

To overcome the above problems, the inventors of the present disclosure have proposed a novel backside illuminated image sensor and a method of manufacturing the same, which will be described in detail later.

The foregoing is intended merely to aid in the understanding of the background of the present disclosure, and is not intended to mean that the present disclosure falls within the purview of the related art that is already known to those skilled in the art.

### Documents of Related Art

(Patent document 1) U.S. Patent No. 9,054,106 B2 “SEMICONDUCTOR STRUCTURE AND METHOD FOR MANUFACTURING THE SAME”

### SUMMARY OF THE INVENTION

Accordingly, the present disclosure has been made keeping in mind the above problems occurring in the related art, and one objective of the present disclosure is to provide a backside illuminated image sensor and a method of manufacturing the same, in which an upper conductive film is not formed on back surfaces of substrates, thereby reducing the thickness of the entire structure formed on the back surface of the substrates, thereby preventing the occurrence of a stripe-like pattern (striation) caused by clumping of a photosensitive solution during a spin coating process.

Another objective of the present disclosure is to provide a backside illuminated image sensor and a method of manufacturing the same, in which an upper conductive film is not formed on back surfaces of substrates, thereby preventing damage to a corner portion of the upper conductive film during formation of the upper conductive film.

Another objective of the present disclosure is to provide a backside illuminated image sensor and a method of manufacturing the same, in which ends of a lower conductive film are located in depressed portions of back surfaces of substrates, thereby further reducing the thickness of the entire structure formed on the back surfaces of the substrates.

In order to achieve the above objectives, according to one aspect of the present disclosure, there is provided a backside illuminated image sensor, including: a pair of substrates spaced apart from each other; a lower insulating film on front surfaces of the substrates; a plurality of metal layers stacked within the lower insulating film and connected to each other by a contact plug; an insulating film extending along sidewalls of the substrates and back surfaces of the substrates within a separation space of the substrates; a lower conductive film connected to the metal layers within the separation space of the substrates and extending along inner sidewalls of the insulating film; and an upper conductive film located on the lower conductive film to be confined in the separation space of the substrates.

According to another aspect of the present disclosure, the upper conductive film may include: a first portion on the lower conductive film directly above the metal layers; and a pair of second portions extending along inner sidewalls of the lower conductive film on the sidewalls of the substrates.

According to another aspect of the present disclosure, each of the second portions may have a spacer cross-sectional shape.

According to another aspect of the present disclosure, an upper end of an inner sidewall of each of the second portions may have a substantially curved cross-sectional shape.

According to another aspect of the present disclosure, a side end of the first portion may be spaced apart from a lower portion of an adjacent second portion.

According to another aspect of the present disclosure, the first potion may be physically connected to the second potions.

According to another aspect of the present disclosure, the upper conductive film may further include a connecting portion connecting the first portion and each of the second portions to each other. An upper surface of the connecting portion may be located lower than an upper surface of the first portion.

According to another aspect of the present disclosure, the upper conductive film may further include a connecting portion connecting the first portion and each of the second portions to each other. An upper surface of the connecting portion may be located at substantially the same height as an upper surface of the first portion, or may be located at a higher height than the upper surface of the first portion.

According to another aspect of the present disclosure, the back surface of each of the substrates may include: a depressed portion adjacent to the separation space of the substrates; and a protruding portion located at a relatively higher position than the depressed portion through a stepped portion on a boundary side with the depressed portion. The insulating film may be located on the depressed portion and the protruding portion, and a side end of the lower conductive film may be located on the depressed portion.

According to another aspect of the present disclosure, an upper surface of the lower conductive film on the depressed portion may be located at substantially the same height as or a lower height than an upper surface of the insulating film on the protruding portion.

According to another aspect of the present disclosure, there is provided a backside illuminated image sensor, including: a pixel region absorbing incident light; a shield region surrounding the pixel region and serving as a light shielding region; and a pad region outside the shield region. The pad region may include: a pair of substrates spaced apart from each other; a wiring region including a metal and on front surfaces of the substrates; an insulating film on sidewalls and back surfaces of the substrates; a lower conductive film on inner sidewalls of the insulating film; and an upper conductive film on the lower conductive film. The upper conductive film may include: a first portion on the lower conductive film directly above the metal layer; and a pair of second portions extending along inner sidewalls of the lower conductive film on the sidewalls of the substrates.

According to another aspect of the present disclosure, the backside illuminated image sensor may further include: a solder ball on the first portion.

According to another aspect of the present disclosure, an upper end of an inner sidewall of each of the second portions may have a substantially curved cross-sectional shape.

According to another aspect of the present disclosure, the second portions may be spaced apart from the adjacent first portion.

According to another aspect of the present disclosure, the upper conductive film may further include a connecting portion connecting the first portion and each of the second portions to each other.

According to another aspect of the present disclosure, there is provided a method of manufacturing a backside illuminated image sensor, the method including: etching a substrate and a lower insulating film on a front surface of the substrate to form a separation space for separating a pair of substrates from each other; forming an insulating film extending along sidewalls of the substrates and back surfaces of the substrates within the separation space of the substrates; forming a lower conductive film connected to a metal layer within the lower insulating film within the separation space of the substrates and extending along inner sidewalls of the insulating film; and forming an upper conductive film on the lower conductive film within the separation space of the substrates. The upper conductive film may include: a first portion on the lower conductive film directly above the metal layers; and a pair of second portions extending along inner sidewalls of the lower conductive film on the sidewalls of the substrates, and each of which having a spacer cross-sectional shape.

According to another aspect of the present disclosure, the lower conductive film and the upper conductive film may be formed by: forming a first conductive film on the metal layer and the insulating film; forming a second conductive film on the first conductive film; completing the upper conductive film by forming a first photoresist film on the second conductive film and then performing an etching process; and completing the lower conductive film by forming a second photoresist film on the first conductive film and in the separation space of the substrates and then performing an etching process.

According to another aspect of the present disclosure, a distance between a side end of the first photoresist film and the sidewall of an adjacent substrate may be within a range of 0.9 μm to 2.0 μm.

According to another aspect of the present disclosure, the completing of the upper conductive film may include entirely removing the second conductive film located on the back surfaces of the substrates.

According to another aspect of the present disclosure, a side of the lower conductive film may be located on the back surface of each of the substrates.

The present disclosure has the following effects by the above configuration.

By not forming the upper conductive film on the back surfaces of the substrates, it is possible to reduce the thickness of the entire structure formed on the back surfaces of the substrates, thereby preventing the occurrence of a stripe-like pattern (striation) caused by clumping of a photosensitive solution during a spin coating process.

Additionally, by not forming the upper conductive film on the back surfaces of the substrates, it is possible to prevent damage to the corner portion of the upper conductive film during formation of the upper conductive film.

Additionally, by locating the ends of the lower conductive film in the depressed portions of the back surfaces of the substrates, it is possible to further reduce the thickness of the entire structure formed on the back surfaces of the substrates.

Meanwhile, the effects of the present disclosure are not limited to those mentioned above, and other effects not mentioned above can be clearly understood from the following description.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a sectional view illustrating the structure of a conventional backside illuminated image sensor;

FIG. 2 is a reference view illustrating a problem occurring during a spin coating process in the structure of the backside illuminated image sensor illustrated in FIG. 1;

FIG. 3 is a view illustrating damage to a corner portion of a conductive film in the structure of the backside illuminated image sensor illustrated in FIG. 1;

FIG. 4 is a plan view illustrating a backside illuminated image sensor according to an embodiment of the present disclosure;

FIG. 5 is a sectional view taken along line AA' of FIG. 4 according to a first embodiment of the present disclosure;

FIG. 6 is a sectional view taken along line AA' of FIG. 4 according to a second embodiment of the present disclosure;

FIG. 7 is a sectional view taken along line AA' of FIG. 4 according to a third embodiment of the present disclosure;

FIG. 8 is a sectional view taken along line AA' of FIG. 4 according to a fourth embodiment of the present disclosure; and

FIGS. 9 to 16 are sectional views illustrating a method of manufacturing a backside illuminated image sensor according to an embodiment of the present disclosure.

### DETAILED DESCRIPTION OF THE INVENTION

Hereinafter, exemplary embodiments of the present disclosure will be described in more detail with reference to the accompanying drawings. The embodiments of the present disclosure can be modified in various forms. Therefore, the scope of the present disclosure should not be construed as being limited to the following embodiments, but should be construed on the basis of the descriptions in the appended claims. The embodiments of the present disclosure are provided for complete disclosure of the present disclosure and to fully convey the scope of the present disclosure to those ordinarily skilled in the art.

As used herein, the singular forms are intended to include the plural forms as well, unless the context clearly indicates otherwise. The terms “comprise” and/or “comprising” means inclusion of a shape, number, process, operations, member, element, and/or a group of those, but do not mean exclusion of or denial of addition of another shape, number, process, operation, element, and/or a group of those.

As used herein, when an element (or layer) is referred to as being disposed on another element (or layer), it can be disposed directly on the other element, or intervening element(s) (or layer(s)) may be disposed therebetween. In contrast, when an element is referred to as being directly disposed on or above another element, intervening element(s) are not located therebetween. Further, the terms “on”, “above”, “below”, “upper”, “lower”, “one side”, “side surface”, etc. are used to describe one element's relationship to another element(s) illustrated in the drawings.

Meanwhile, when one embodiment is implemented differently, individual processes may be performed in a different order than described in the specification. For example, two consecutive processes may be performed substantially at the same time or performed in an order opposite to the described order.

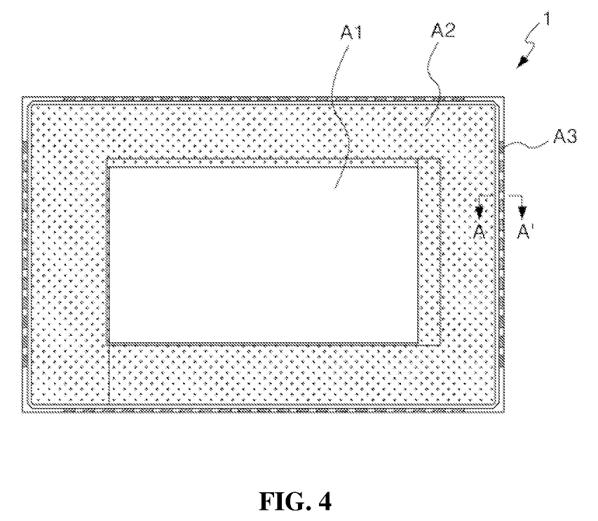

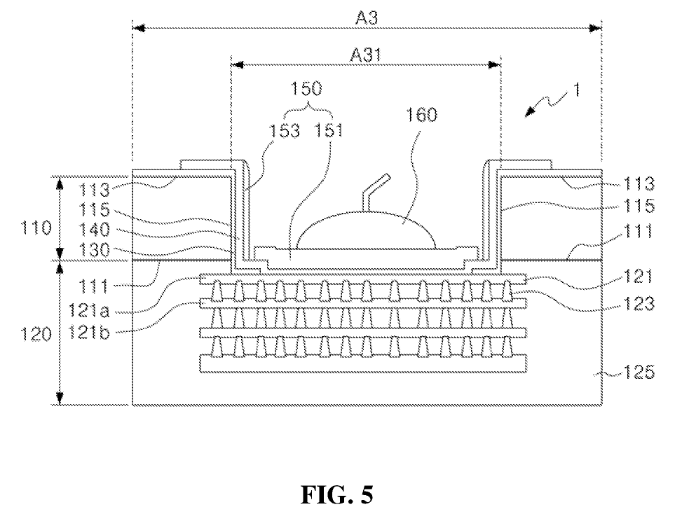

FIG. 4 is a plan view illustrating a backside illuminated image sensor according to an embodiment of the present disclosure; and FIG. 5 is a sectional view taken along line AA' of FIG. 4 according to a first embodiment of the present disclosure;

Hereinafter, the backside illuminated image sensor 1 according to the embodiment of the present disclosure will be described in detail with reference to the accompanying drawings.

Referring to FIGS. 4 and 5, the present disclosure relates generally to a backside illuminated image sensor 1. More particularly, the present disclosure relates to a backside illuminated image sensor 1, in which an upper conductive film 150 is formed within a separation space A31 of substrates 110 but is not formed on back surfaces 113 of the substrates 110, thereby reducing the overall thickness of a structure formed on the back surfaces 113 of the substrates 110 within a pad region A3, thereby preventing a stripe-like pattern (striation) from forming on the substrates 110 and preventing damage to a corner portion of the upper conductive film 150.

Referring to FIG. 4, the backside illuminated image sensor 1 according to the embodiment of the present disclosure may include a pixel region A1, a shield region A2 surrounding the pixel region A1, and a pad region A3 outside the shield region A2. The pixel region A1 is a region that absorbs light incident from the outside, the shield region A2 is a light shielding region, and the pad region A3 is a region where a contact pad is formed. Additionally, within the pad region A3, a separation space A31 where a substrate 110 is etched and the substrate 110 does not exist may be formed between a pair of substrates 110.

Hereinafter, the structure of the backside illuminated image sensor 1 within the pad region A3 will be described in detail with reference to FIG. 5. First, the backside illuminated image sensor 1 may be provided with the substrate 110. The substrate 110 is a silicon (Si) substrate, and may include, for example, an epitaxial substrate, a bulk substrate, or the like. As described above, within the pad region A3, the substrate 110 may be etched at a predetermined position, so the separation space A31 for separating the pair of substrates 110 from each other may be formed. That is, the substrates 110 may be disposed on the left and right sides of the separation space A31. Additionally, each of the substrates 110 may have a front surface 111, a back surface 113, and a sidewall 115 on a boundary side of the separation space A31.

A wiring region 120 may be formed on the front surfaces 111 of the substrates 110. The wiring region 120 may include a metal layer 121, a contact plug 123, and a lower insulating film 125.

The metal layer 121 may be formed by, for example, a single metal or an alloy film in which different types of metals are mixed, and preferably includes, for example, an aluminum (Al) film. However, the scope of the present disclosure is not limited thereto. Additionally, a plurality of metal layers 121 may be stacked to form a multi-layer structure within the lower insulating film 125. For example, a first metal layer 121a may be formed on a side closest to the back surfaces 113 of the substrates 110, and a second metal layer 121b may be formed under the first metal layer 121a, but there is no separate limitation on the total number of metal layers.

Additionally, each metal layer 121 may be electrically connected to an adjacent metal layer 121 by the contact plug 123. The contact plug 123 may be formed in the lower insulating film 125, for example, through a damascene process. In order to electrically connect the contact plug 123 to the metal layers 121, the contact plug 123 may be formed by at least any one conductive material selected from the group consisting of a polycrystalline silicon film doped with impurity ions, a metal, and an alloy film in which different types of metals are mixed.

Additionally, the lower insulating film 125 may be formed by, for example, any one oxide layer selected from the group consisting of BPSG, PSG, BSG, USG, TEOS, and HDP or a stacked layer in which at least two layers selected from the aforementioned group are mixed. Additionally, the lower insulating film 125 may be planarized, for example, through a CMP process after deposition.

An insulating film 130 may be formed within the separation space A31 of the substrates 110. For example, the insulating film 130 may be formed to extend along the sidewalls 115 and the back surfaces 113 of the substrates 110. In some cases, the insulating film 130 may also be formed to extend a predetermined distance to the first metal layer 121a. The insulating film 130 may include, for example, a silicon oxide film, a silicon nitride film, or a silicon oxynitride film, but the scope of the present disclosure is not limited by the above examples.

Additionally, a lower conductive film 140 may be formed on the insulating film 130. The lower conductive film 140 may be a film including, for example, tungsten (W) and may be physically connected to the first metal layer 121a. For example, the lower conductive film 140 may be formed on the first metal layer 121a and may also be formed on inner sidewalls of the insulating film 130 formed along the sidewalls 115 of the substrates 110. Additionally, the lower conductive film 140 may or may not be formed on the insulating film 130 on the back surfaces 113 of the substrates 110. It is preferable that the lower conductive film 140 is formed continuously without interruption. Additionally, when the lower conductive film 140 extends from the back surfaces 113 of the substrates 110 to the shield region A2, the lower conductive film 140 may also function as a shield layer for blocking light.

Additionally, the upper conductive film 150 may be formed on the lower conductive film 140. It is preferable that the upper conductive film 150 is formed within the separation space A31 of the substrates 110 and is not formed on the back surfaces 113 of the substrates 110. That is, the upper conductive film 150 may be formed only within the separation space A31 of the substrates 110. The upper conductive film 150 may be formed by, for example, a single metal such as titanium (Ti), titanium nitride (TiN), or aluminum (Al), or an alloy film containing different types of metals, but the scope of the present disclosure is not limited by the above examples. In detail, the upper conductive film 150 may have a first portion 151 and a pair of second portions 153.

The first portion 151 may be formed on an upper surface of the lower conductive film 140 formed directly above the first metal layer 121a. At this time, the upper surface of the first portion 151 may be substantially flat, or may be formed with a stepped side. Additionally, the second portions 153 may form sidewalls of the upper conductive film 150 formed along the inner sidewalls of the lower conductive film 140 on the sidewalls 115 of the substrates 110 within the separation space A31. At this time, each of the second portions 153 may have a spacer cross-sectional shape. That is, an upper end of an inner sidewall of each of the second portions 153 may have a substantially curved cross-sectional shape. Additionally, the second portions 153 may be respectively formed on the sidewalls 115 of the substrates 110 facing each other.

Hereinafter, various cross-sectional shapes of the upper conductive film 150 will be described in detail.

According to the first embodiment, a first portion 151 and a pair of second portions 153 of an upper conductive film 150 may be spaced apart from each other by a predetermined distance. That is, a side end of the first portion 151 and lower ends of the second portions 153 may not be connected to each other and physically separated from each other. At this time, among the pair of second portions 153 on the left and right sides of the first portion 151, only the second portion 153 on one side may be separated from the first portion 151, and the remaining second portion 153 may be connected to the first portion 151.

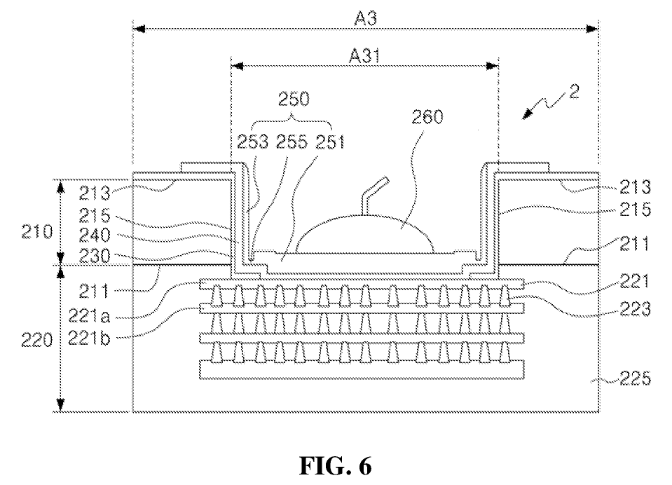

FIG. 6 is a sectional view taken along line AA' of FIG. 4 according to a second embodiment of the present disclosure.

A backside illuminated image sensor 2 according to the second embodiment will be described with reference to FIG. 6. A first portion 251 and a pair of second portions 253 of an upper conductive film 250 may be connected to each other without interruption. That is, the first portion 251 and the second portions 253 may not have sides that are spaced apart from each other. Hereinafter, a side where the first portion 251 and each of the second portions 253 are connected to each other is referred to as a “connecting portion 255”. An upper surface of the connecting portion 255 may be located lower than an upper surface of the first portion 251. Accordingly, due to the connecting portion 255, the upper conductive film 250 may have a downwardly depressed cross-sectional shape between the first portion 251 and the second portions 253.

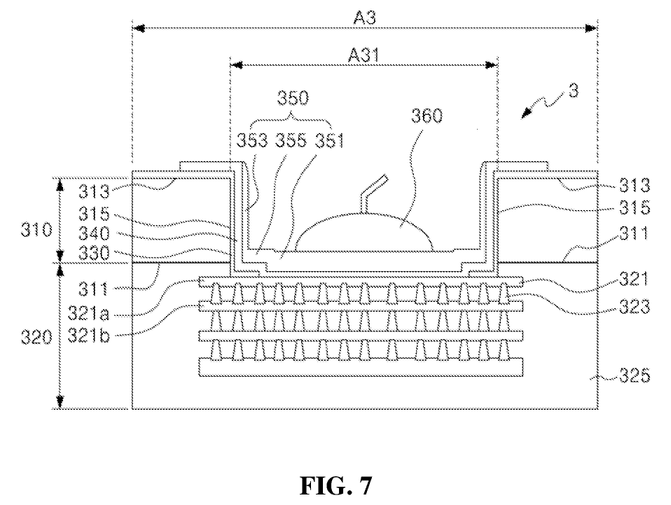

FIG. 7 is a sectional view taken along line AA' of FIG. 4 according to a third embodiment of the present disclosure.

A backside illuminated image sensor 3 according to the third embodiment will be described with reference to FIG. 7. An upper surface of a connecting portion 355 between a first portion 351 and each of a pair of second portions 353 may be formed at substantially the same height as an upper surface of the adjacent first portion 351, or may be formed at a higher height than the upper surface of the first portion 351.

The cross-sectional shapes of the upper conductive films according to the first to third embodiments may be controlled by adjusting the distance between a mask pattern for forming the upper conductive film and the sidewalls 115 of the substrates 110. A detailed description thereof will be provided in a “Method of manufacturing a backside illuminated image sensor”, which will be described later.

Referring to FIG. 5, a solder ball 160 may be formed on the upper conductive film 150 within the separation space A31 of the pad region A3. The solder ball 160 may include, for example, gold (Au) or nickel (Ni), but the scope of the present disclosure is not limited by the above examples.

Hereinafter, the structure of a conventional backside illuminated image sensor 9 within a pad region A3 and the problems arising therefrom will be described in detail with reference to the accompanying drawings.

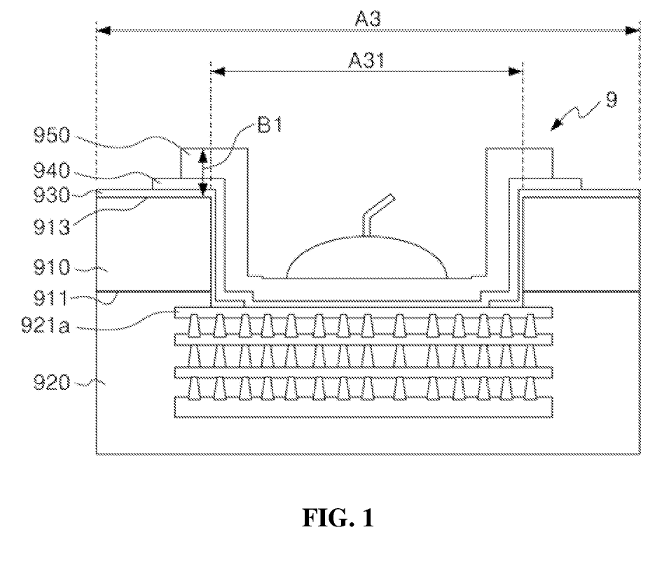

As described above, referring to FIG. 1, the conventional backside illuminated image sensor 9 includes a lower insulating film 920 on front surfaces 911 of a pair of substrates 910 within the pad region A3. Additionally, an adhesive layer 940 is formed on a metal layer 921a formed in a separation space A31 of the substrates 910, and a conductive film 950 is formed on the adhesive layer 940. Additionally, an insulating film 930 is formed between the adhesive layer 940 and the substrates 910. At this time, the conductive film 950 extends from the adhesive layer 940 in the separation space A31 of the substrates 910 to sidewalls of the substrates 910 and back surfaces 913 of the substrates 910. That is, the conductive film 950 is formed on the adhesive layer 940 on the back surfaces 913 of the substrates 910. Accordingly, due to the insulating film 930, the adhesive layer 940, and the conductive film 950 formed on the back surfaces 913 of the substrates 910 within the pad region A3, a thickness B of the entire structure formed on the back surfaces 913 is likely to be relatively large.

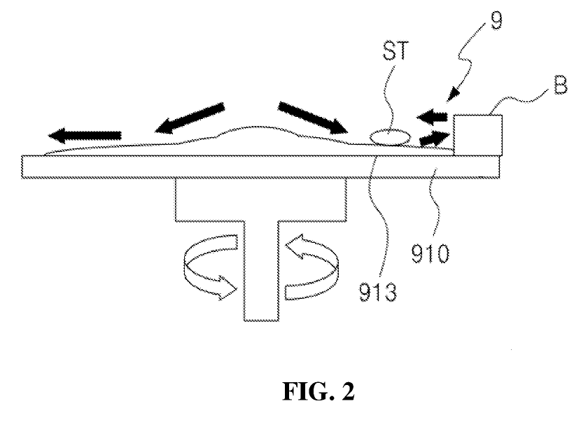

Referring to FIG. 2, when forming a color filter and/or micro-lens of the backside illuminated image sensor 9, a spin coating process is performed on a photosensitive liquid. At this time, the photosensitive liquid may not be evenly applied due to the structure formed on the back surface 913 of the substrate 910, but clump on a side adjacent to the structure, resulting in a stripe-like pattern ST formed on the substrate 910. This may act as a factor causing poor appearance and color deviation of the image sensor 9.

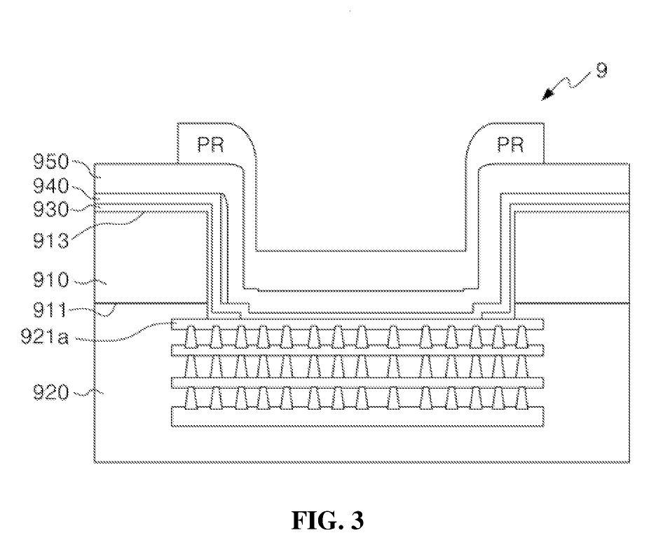

Furthermore, referring to FIG. 3, when forming a photoresist film PR on the conductive film 950 on the back surfaces 913 of the substrates 910 to complete the conductive film 950, a corner portion of the photoresist film PR is formed relatively thin, so loss is likely to occur in the conductive film 950 directly below the photoresist film PR. As a result, a problem arises in that a corner portion of the completed conductive film 950 may be damaged.

Referring to FIG. 5, in order to the above problems, the upper conductive film 150 of the backside illuminated image sensor 1 according to the embodiment of the present disclosure is formed only within the separation space A31, but is not formed on the back surfaces 113 of the substrates 110. Accordingly, the overall height of the structures (insulating film 130, lower conductive film 140, and upper conductive film 150) on the back surfaces 113 of the substrates 110 may be reduced, thereby relatively suppressing the possibility of forming a stripe-like pattern (striation) during the spin coating process, and relatively suppressing the possibility of damage to the corner portion of the upper conductive film 150.

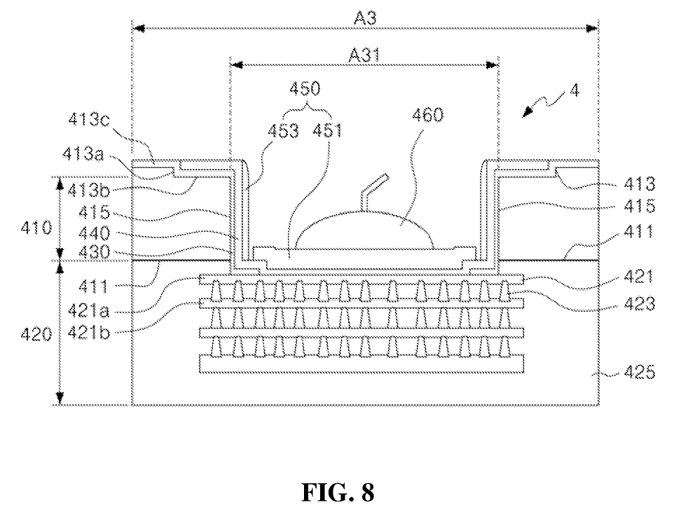

FIG. 8 is a sectional view taken along line AA' of FIG. 4 according to a fourth embodiment of the present disclosure.

Hereinafter, a backside illuminated image sensor 4 according to the fourth embodiment of the present disclosure will be described in detail. In describing the backside illuminated image sensor 4 according to the fourth embodiment, only the structural difference from the backside illuminated image sensor 1 according to the first embodiment will be described in detail.

Referring to FIG. 8, in the backside illuminated image sensor 4 according to the fourth embodiment of the present disclosure, a back surface 413 of each of a pair of substrates 410 may have a stepped portion 413a. That is, the back surface 413 of the substrate 410 may be formed to have a height that is increased by the stepped portion 413a when extending outward from a side adjacent to a separation space A31. Hereinafter, a region with a relatively low height on the back surface 413 of the substrate 410 is referred to as a depressed portion 413b, and a region with a relatively high height is referred to as a protruding portion 413c.

An insulating film 430 may be formed on the back surfaces 413 of the substrates 410. A lower conductive film 440 may be formed to extend from sidewalls 415 of the substrates 410 within the separation space A31 of the substrates 410 to the depressed portions 413b of the substrates 410. At this time, it is preferable that an upper surface of the lower conductive film 440 on the back surfaces 413 of the substrates 410 is located at substantially the same height as or a lower height than an upper surface of the insulating film 430 on the protruding portions 413c. As described above, by further reducing the height of the structures on the back surfaces 413 of the substrates 410, the possibility of occurrence of the aforementioned problems may be further suppressed.

Additionally, in FIG. 8, it is illustrated that a first portion 451 and a pair of second portions 453 may be spaced apart from each other. However, the first portion 451 and the second portions 453 may be connected to each other as in the second and third embodiments.

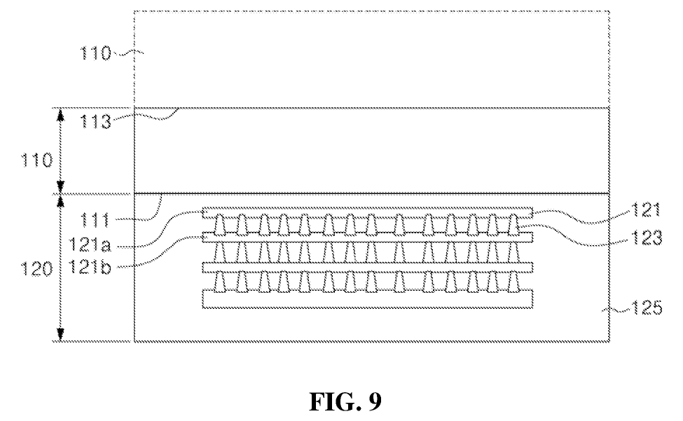

FIGS. 9 to 16 are sectional views illustrating a method of manufacturing a backside illuminated image sensor according to an embodiment of the present disclosure.

Hereinafter, a method of manufacturing the backside illuminated image sensor according to the first embodiment of the present disclosure will be described in detail with reference to the accompanying drawings. A process after a wiring region 120 is formed on a back surface 111 of a substrate 110 will be described in detail.

Referring to FIG. 9, first, a thinning process is performed on the substrate 110. The thinning process is a process of polishing the back surface 113 of the substrate 110, and may be performed, for example, through a CMP process.

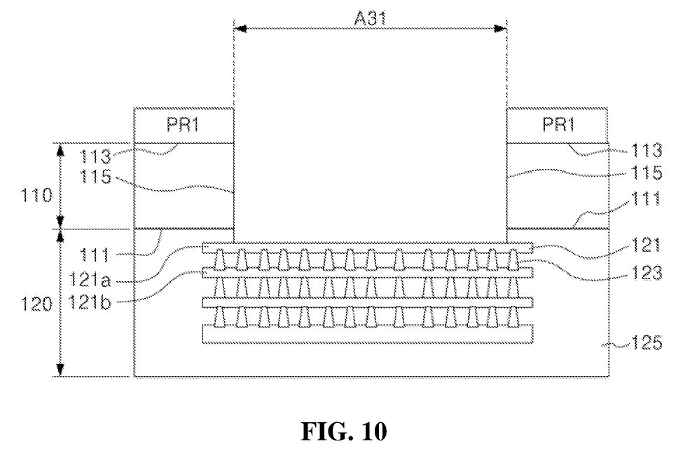

Referring to FIG. 10, the substrate 110 and a lower insulating film 125 are then etched to form a separation space A31 of a pair of substrates 110 and expose a side of an upper surface of a first metal layer 121a. This process may be performed by forming a photoresist film PR1 on the back surface 113 of the substrate 110 and then performing an etching process. When the etching process is completed, the photoresist film PR1 is removed. Thereafter, in order to form back surfaces 413 of the substrates 410 into a stepped shape as in the fourth embodiment, an additional etching process may be performed on a side of each of the back surfaces 413 of the substrates 410.

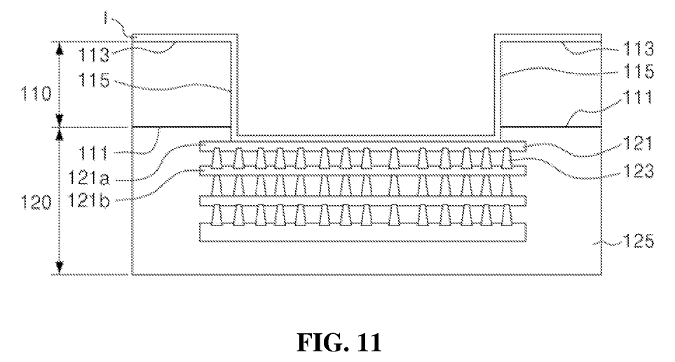

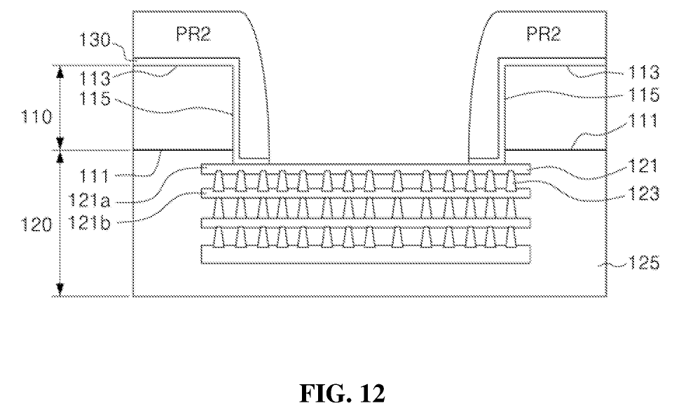

Then, an insulating film 130 is formed. Hereinafter, a process of forming the insulating film 130 will be described. Referring to FIG. 11, first, an insulating film layer I is formed on the first metal layer 121a, sidewalls 115 of the pair of substrates 110, and the back surfaces 113 of the substrates 110. Referring to FIG. 12, after forming a photoresist film PR2 on the insulating film layer I, an etching process is performed on the insulating film layer I to complete the insulating film 130. When the insulating film 130 is completed, at least a side of the upper surface of the first metal layer 121a may be exposed. After the insulating film 130 is completed, the photoresist film PR2 is removed. The etching process for the insulating film layer I may be, for example, an anisotropic etching process.

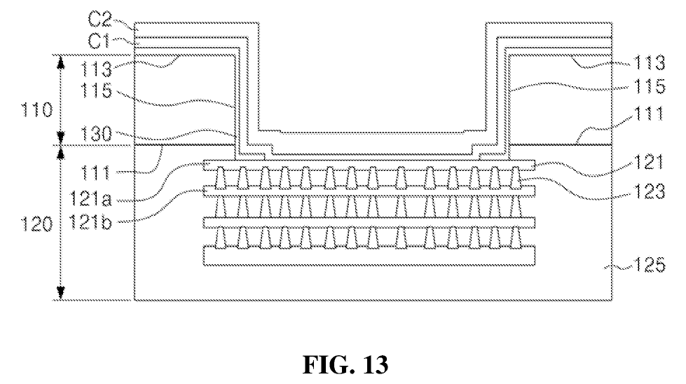

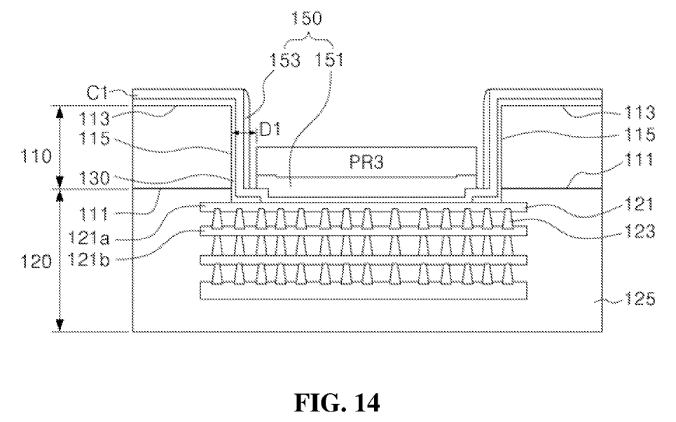

Thereafter, a lower conductive film 140 and an upper conductive film 150 are formed. Hereinafter, a process of forming the lower conductive film 140 and the upper conductive film 150 will be described. Referring to FIG. 13, first, a first conductive film C1 made of, for example, tungsten (W) is formed on the first metal layer 121a and the insulating film 130, and then a second conductive film C2 made of, for example, aluminum (Al) is formed on the first conductive film C1. Referring to FIG. 14, after forming a photoresist film PR3 on the second conductive film C2, an etching process is performed to complete the upper conductive film 150. Thereafter, the photoresist film PR3 is removed. The etching process for the second conductive film C2 may be, for example, an anisotropic etching process.

At this time, it is preferable that a side end of the photoresist film PR3 is spaced apart from the sidewall 115 of an adjacent substrate 110 by a predetermined distance D1. For example, the side end of the photoresist film PR3 may be spaced apart from the sidewall 115 of the adjacent substrate 110 within a range of about 0.9 μm to 2.0 μm. When the side end of the photoresist film PR3 is spaced apart from the sidewall 115 of the adjacent substrate 110 by a distance of less than about 0.9 μm, the upper conductive film 150 may have a side formed on the back surface 113 of the substrate 110 or may be formed at a higher position than the back surface 113 of the substrate 110. Additionally, when the side end of the photoresist film PR3 is spaced apart from the sidewall 115 of the adjacent substrate 110 by a distance exceeding about 2.0 μm, there is a problem of increasing a chip size.

When the distance between the side end of the photoresist film PR3 and the sidewall 115 of the adjacent substrate 110 is within a range of about 0.9 μm to 2.0 μm and the distance between the side end of the photoresist film PR3 and the sidewall 115 of the adjacent substrate 110 is increased within the above range, the first portion 151 and the second portions 153 may be spaced apart from each other as in the first embodiment, or the connecting portion 255 may have a downwardly depressed cross-sectional shape as in the second embodiment. Additionally, when the distance between the side end of the photoresist film PR3 and the sidewall 115 of the adjacent substrate 110 is decreased, the upper surface of the connecting portion 355 may be formed at substantially the same height as the upper surface of the adjacent first portion 351 as in the third embodiment, or may be formed at a higher height than the upper surface of the first portion 351.

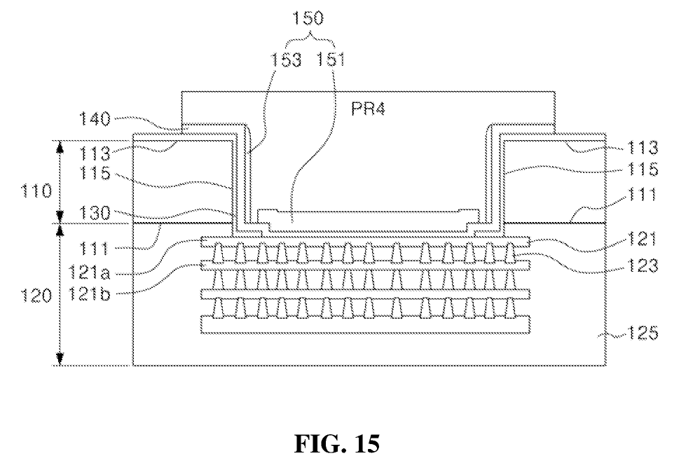

Referring to FIG. 15, after the upper conductive film 150 is completed, a photoresist film PR4 is formed on the first conductive film C1 and in the separation space A31, and then an etching process is performed on the first conductive film C1 to complete the lower conductive film 140. When the lower conductive film 140 is completed, the photoresist film PR4 is removed. The etching process for the first conductive film C1 may be, for example, an anisotropic etching process. During this process, the first conductive film C1 on the back surfaces 113 of the substrates 110 may be removed, or at least a part of the first conductive film C1 may not be removed.

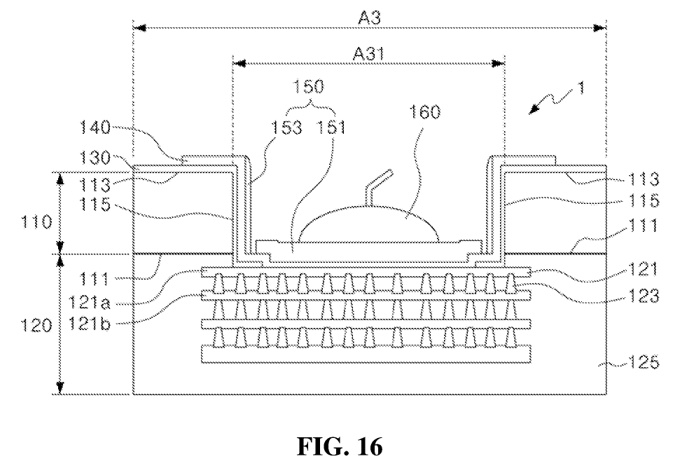

Referring to FIG. 16, a solder ball 160 is then formed on the upper conductive film 150 within the separation space A31.

The foregoing detailed description may be merely an example of the present disclosure. Also, the inventive concept is explained by describing the preferred embodiments and will be used through various combinations, modifications, and environments. That is, the inventive concept may be amended or modified without departing from the scope of the technical idea and/or knowledge in the art. The foregoing embodiments are for illustrating the best mode for implementing the technical idea of the present disclosure, and various modifications may be made therein according to specific application fields and uses of the present disclosure. Therefore, the foregoing detailed description of the present disclosure is not intended to limit the inventive concept to the disclosed embodiments.

What is claimed is:

1. A backside illuminated image sensor, comprising:
a pair of substrates spaced apart from each other;
a lower insulating film disposed on front surfaces of the pair of substrates;
a plurality of metal layers stacked within the lower insulating film and connected to each other by a contact plug;
an insulating film extending along sidewalls of the pair of substrates and back surfaces of the pair of substrates within a separation space of the pair of substrates;
a lower conductive film connected to the plurality of metal layers within the separation space of the pair of substrates, the lower conductive film extending along inner sidewalls of the insulating film; and
an upper conductive film disposed on the lower conductive film to be confined in the separation space of the pair of substrates.

2. The backside illuminated image sensor of claim 1,
wherein the upper conductive film comprises:
a first portion disposed on the lower conductive film directly above the plurality of metal layers; and
a pair of second portions extending along inner sidewalls of the lower conductive film on the sidewalls of the pair of substrates.

3. The backside illuminated image sensor of claim 2, wherein each of the pair of second portions has a spacer cross-sectional shape.

4. The backside illuminated image sensor of claim 2, wherein an upper end of an inner sidewall of each of the pair of second portions has a substantially curved cross-sectional shape.

5. The backside illuminated image sensor of claim 2, wherein a side end of the first portion is spaced apart from a lower portion of the second portion that is adjacent to the side end.

6. The backside illuminated image sensor of claim 2, wherein the first portion is physically connected to the pair of second portions.

7. The backside illuminated image sensor of claim 6,
wherein the upper conductive film further comprises a connecting portion connecting the first portion and each of the pair of second portions,
wherein an upper surface of the connecting portion is positioned lower than an upper surface of the first portion.

8. The backside illuminated image sensor of claim 6,
wherein the upper conductive film further comprises a connecting portion connecting the first portion and each of the pair of second portions to each other,
wherein an upper surface of the connecting portion is positioned at substantially a same height as an upper surface of the first portion, or is positioned at a higher height than the upper surface of the first portion.

9. The backside illuminated image sensor of claim 1,
wherein the back surface of each of the pair of substrates comprises:
a depressed portion adjacent to the separation space of the pair of substrates; and
a protruding portion disposed at a higher position than the depressed portion through a stepped portion on a boundary side by the depressed portion,
wherein the insulating film is disposed on the depressed portion and the protruding portion, and
wherein a side end of the lower conductive film is disposed on the depressed portion.

10. The backside illuminated image sensor of claim 9, wherein an upper surface of the lower conductive film on the depressed portion is positioned at substantially a same height as or a lower height than an upper surface of the insulating film disposed on the protruding portion.

11. A backside illuminated image sensor, comprising:
a pixel region configured to absorb incident light;
a shield region surrounding the pixel region, the shield region being configured to serve as a light shielding region; and
a pad region disposed outside the shield region,
wherein the pad region comprises:
a pair of substrates spaced apart from each other;
a wiring region comprising a metal layer and disposed on front surfaces of the pair of substrates;
an insulating film disposed on sidewalls and back surfaces of the pair of substrates;
a lower conductive film disposed on inner sidewalls of the insulating film; and
an upper conductive film disposed on the lower conductive film,
wherein the upper conductive film comprises:
a first portion disposed on the lower conductive film directly above the metal layer; and
a pair of second portions extending along inner sidewalls of the lower conductive film on the sidewalls of the pair of substrates.

12. The backside illuminated image sensor of claim 11, further comprising:
a solder ball disposed on the first portion.

13. The backside illuminated image sensor of claim 11, wherein an upper end of an inner sidewall of each of the pair of second portions has a substantially curved cross-sectional shape.

14. The backside illuminated image sensor of claim 11, wherein the pair of second portions are spaced apart from the adjacent first portion.

15. The backside illuminated image sensor of claim 11, wherein the upper conductive film further comprises a connecting portion connecting the first portion and each of the pair of second portions to each other.

16. A method of manufacturing a backside illuminated image sensor, the method comprising:
etching a substrate and a lower insulating film on a front surface of the substrate to form a separation space for separating a pair of substrates from each other;
forming an insulating film extending along sidewalls of the pair of substrates and back surfaces of the pair of substrates within the separation space of the pair of substrates;
forming a lower conductive film connected to a metal layer within the lower insulating film within the separation space of the pair of substrates, the lower conductive film extending along inner sidewalls of the insulating film; and
forming an upper conductive film on the lower conductive film within the separation space of the pair of substrates,
wherein the upper conductive film comprises:
a first portion disposed on the lower conductive film directly above the metal layer; and
a pair of second portions extending along inner sidewalls of the lower conductive film on the sidewalls of the pair of substrates, each of the pair of second portions having a spacer cross-sectional shape.

17. The method of claim 16, wherein the lower conductive film and the upper conductive film are formed by:
forming a first conductive film on the metal layer and the insulating film;
forming a second conductive film on the first conductive film;
completing the upper conductive film by forming a first photoresist film on the second conductive film and then performing an etching process; and
completing the lower conductive film by forming a second photoresist film on the first conductive film and in the separation space of the pair of substrates and then performing an etching process.

18. The method of claim 17, wherein a distance between a side end of the first photoresist film and the sidewall of an adjacent substrate of the pair of substrates is within a range of 0.9 μm to 2.0 μm.

19. The method of claim 16, wherein the completing of the upper conductive film comprises entirely removing the second conductive film located on the back surfaces of the pair of substrates.

20. The method of claim 16, wherein a side of the lower conductive film is located on the back surface of each of the pair of substrates.
